(19) United States
(12) Patent Application Publication
(10) Pub. No.: US 2010/0059767 A1
(43) Pub. Date: Mar. 11, 2010

(54) Surface Light-Emitting Device and Display Device Using the Same

(75) Inventors: Yoji KAWASAKI, Imabari-shi (JP); Ryuji TSUCHIYA, Imabari-shi (JP)

Correspondence Address: BANNER & WITCOFF, LTD.;ATTORNEYS FOR CLIENT NO. 000449, 001701, 1100 13th STREET, N.W., SUITE 1200, WASHINGTON, DC, 20005-4051, US

(73) Assignee: HARISON TOSHIBA LIGHTING CORPORATION, Imabari-shi (JP)

(21) Appl. No.: 12/555,856

(22) Filed: Sep. 9, 2009

(30) Foreign Application Priority Data
Sep. 10, 2008 (JP) 2008-232129

(51) Int. Cl. H01L 33/00

(52) U.S. Cl. 257/89; 257/E33.067

(57) ABSTRACT

A surface light-emitting device is disclosed, in which a plurality of spot light sources are arranged along the side surface of a housing of the device, and the light emitted from the spot light sources located at the end portions of the spot light source sequence emits a lower light flux than the average light flux of the light emitted from the other spot light sources. The spot light source sequence is, for example, an LED array including an alignment of light-emitting diodes (LEDs). The LED array includes two groups of LED elements arranged in a predetermined repetitive pattern from one and the other ends, respectively, of the LED array, and at least an LED emitting low light flux is arranged at a predetermined position in the vicinity of the center of the array. As a result, the requirement for a reduced thickness and a narrower frame can be met, while at the same time producing the white light of uniform chromaticity over the whole light-emitting surface.

### CROSS REFERENCE TO RELATED APPLICATIONS

This application is based upon and claims the benefit of priority from the prior Japanese Patent Application No. 2008-232129 filed in Japan on Sep. 10, 2008; the entire contents of which are incorporated herein by reference.

### BACKGROUND OF THE INVENTION

1. Field of the Invention

The present invention relates to a surface light-emitting device usable, for example, as a backlight unit of a liquid crystal display device, an illumination device using surface light emission and a display device having the surface light-emitting device as a light source.

2. Description of the Related Art

The recent trend is for a light-emitting diode (LED) to replace a cold cathode fluorescent lamp (CCFL) widely used as a light source of a backlight unit for a liquid crystal display device. This is mainly due to the fact that the LED does not contain mercury, which is a harmful material, and is more suitable as an environment-friendly light source on the one hand and the current trend toward power saving by a remarkable improvement in light-emission efficiency on the other hand. Although the backlight unit having the LED as a light source has been mainly used for small devices such as a portable telephone and other mobile terminals up to the present, the trend is enhanced now to employ the LED backlight unit also for large-sized display devices such as a 20-inch or larger liquid crystal monitor and liquid crystal TV. The backlight for the large-sized display devices is required to have a higher brightness, and therefore, a direct backlight in which the LED light sources are arranged in a matrix-like manner on the back of the light-emitting surface is generally employed (see, for example, Japanese Patent Application Laid-Open No. 2005-316337).

The LED direct backlight, however, poses the problem that brightness and chromaticity irregularities occur on the light-emitting surface. Specifically, as compared with the conventional CCFL which is a bar-like light source and emits light through a phosphor coating formed on the internal surface of a fluorescent tube, the LED constituting a spot light source has the disadvantage that light emitted from each LED unit is visually undesirably recognized as a bright spot unless the emitted light is sufficiently scattered or mixed.

In one attempt to solve this problem, Japanese Patent Application Laid-Open No. 2006-106212 discloses a backlight unit employing a side light system in which a plurality of LEDs are arranged in one or a plurality of rows on a circuit board on a side surface of a unit case, and the light emitted from the LEDs is reflected on the bottom and side surfaces of the unit case to produce a planar light emission. In the side light system for producing the surface light emission by arranging monochromatic LEDs of red (R), green (G), blue (B) and the like, however, the chromaticity may vary from one area to another on the light-emitting surface due to the difference in the mixing conditions of the emitted light between the end portions and the central portion of the LED array. This document also contains description suggesting the possibility to address this disadvantage by using a greater number of green LEDs generally smaller in light emission amount than the red and blue LEDs. In this case, however, the irregular arrangement of the LEDs causes the chromaticity irregularities.

Japanese Patent Application Laid-Open No. 2002-109936 discloses an invention in which the intervals of the LEDs arranged are adjusted and LEDs of different chromaticity ranks are arranged at the center and the end portions of the LED array or in which low-brightness LEDs are arranged on a side from which resin is injected, to thereby reduce the chromaticity and brightness irregularities. The arrangement of a plurality of LEDs of different chromaticity ranks in different areas, however, poses the problem that the emitted colors and the color rendering properties vary from one light emitting area to another when light is mixed.

### SUMMARY

The present invention has been made in view of the technical problems of the prior art described above and an object thereof is to provide a surface light-emitting device of a side light type which can contribute to a thinner device and produce light having uniform brightness and chromaticity over the whole light-emitting surface.

In this specification, “a side light type” or “a side light system” refers to a surface light-emitting system in which the light emitted from a light source unit arranged on a side of a back portion of the light-emitting surface of the device is guided in planar manner, or the light emitted from each light source is refracted, reflected or diffused to produce a planar light emission.

A surface light-emitting device according to one aspect of the invention comprises a hollow housing having a reflection surface arranged on a bottom surface thereof and a light-emitting surface arranged at a position in opposed relation to the reflection surface, and a plurality of spot light sources arranged along at least one side surface of the housing to emit light of different colors, wherein light emitted from spot light sources located at the ends of a spot light source sequence having the plurality of the spot light sources has a light flux lower than averaged light flux of the light emitted from the other spot light sources.

In addition, a surface light-emitting device according to one aspect of the invention comprises a hollow housing having a reflection surface arranged on a bottom surface thereof and a light-emitting surface arranged at a position in opposed relation to the reflection surface, and an LED array with a plurality of LED elements arranged along at least one side surface of the housing, wherein the LED array includes n types (n: a natural number of 3 or more) of LED elements having different light emission colors, wherein sequences of the LED elements in the LED array are arranged to include a first sequence pattern in which n LED elements including a first LED element having a first light emission color to a nth LED element having an nth light emission color are arranged repeatedly in the order of 1, 2, 3, . . . , n from one end of the LED array, a second sequence pattern in which n LED elements including a first LED element having a first light emission color to a nth LED element having an nth light emission color are arranged repeatedly in the order of 1, 2, 3, . . . , n from the other end of the LED array, and a third sequence pattern formed at the intermediate position between the first sequence pattern and the second sequence pattern, wherein given that the same type of LED elements are arrayed adjacent to each other in the third sequence pattern, one of the adjacent LED elements is removed from the array and the light emitted from two LED elements arranged adjacent to the remaining LED element on both sides and the first LED elements at the end portions of the LED array is lower in light flux than the light emitted from the LED elements of the same type located at the other portions.

In a surface light-emitting device according to still another aspect of the invention, the LED array includes at least three types of LED elements for emitting red (R), green (C) and blue (B), respectively, and in the case where the LED element sequence after removing one of the two adjacent LED elements of the same type at the third sequence patterns results in GRG or GBG, a series of these LED elements GRG or GBG is replaced by one LED element for emitting G.

### BRIEF DESCRIPTION OF THE DRAWINGS

FIG. 1 is an exploded perspective view of a backlight unit according to a first embodiment of the invention;

FIG. 2 is a partial sectional view of the backlight unit shown in FIG. 1;

FIG. 3 is a sectional view for explaining the operation of a collimator lens for converging the light emitted from the LED elements of the backlight unit shown in FIG. 1;

FIG. 4 is a perspective view for explaining the configuration of an LED element array of the backlight unit shown in FIG. 1;

FIG. 5 is schematic diagram for explaining an LED element array configured according to the features of the invention;

FIG. 6 is an exploded perspective view of a backlight unit according to a second embodiment of the invention;

FIG. 7 is an exploded perspective view of a backlight unit according to a third embodiment of the invention;

FIG. 8A is a graph showing the result of measuring the chromaticity distribution of a backlight unit according to an Example of the invention;

FIG. 8B is a graph showing, as a comparison with FIG. 8A, the result of measuring the chromaticity distribution of a backlight unit according to a Comparative Example;

FIG. 9A is a graph showing a result of simulating the chromaticity distribution of a backlight unit according to an Example of the invention with the sequence of the LED array changed;

FIG. 9B is a graph showing a result of simulating the chromaticity distribution of a backlight unit according to a Comparative Example with the sequence of the LED array changed;

FIG. 10A is a graph showing the result of simulating the chromaticity distribution of a backlight unit according to an Example of the invention with the sequence of the LED array changed;

FIG. 10B is a graph showing, as a comparison with FIG. 10A, the result of simulating the chromaticity distribution of a backlight unit according to a Comparative Example with the sequence of the LED array changed;

FIG. 11A is a graph showing the result of simulating the chromaticity distribution of a backlight unit according to an Example of the invention with the sequence of the LED array changed;

FIG. 11B is a graph showing, as a comparison with FIG. 11A, the result of simulating the chromaticity distribution of a backlight unit according to a Comparative Example with the sequence of the LED array changed;

FIG. 12A is a graph showing the result of simulating the chromaticity distribution of a backlight unit according to an Example of the invention with the sequence of the LED array changed;

FIG. 12B is a graph showing, as a comparison with FIG. 12A, the result of simulating the chromaticity distribution of a backlight unit according to a Comparative Example with the sequence of the LED array changed;

FIG. 13A is a graph showing the result of simulating the chromaticity distribution of a backlight unit according to an Example of the invention with the sequence of the LED array changed;

FIG. 13B is a graph showing, as a comparison with FIG. 13A, the result of simulating the chromaticity distribution of a backlight unit according to a Comparative Example with the sequence of the LED array changed;

FIG. 14A is a graph showing the result of simulating the chromaticity distribution of a backlight unit according to an Example of the invention with the sequence of the LED array changed;

FIG. 14B is a graph showing, as a comparison with FIG. 14A, the result of simulating the chromaticity distribution of a backlight unit according to a Comparative Example with the sequence of the LED array changed;

FIG. 15A is a graph showing the result of simulating the chromaticity distribution of a backlight unit according to an Example of the invention with the sequence of the LED array changed;

FIG. 15B is a graph showing, as a comparison with FIG. 15A, the result of simulating the chromaticity distribution of a backlight unit according to a Comparative Example with the sequence of the LED array changed;

FIG. 16A is a graph showing the result of simulating the chromaticity distribution of a backlight unit according to an Example of the invention with the sequence of the LED array changed;

FIG. 16B is a graph showing, as a comparison with FIG. 16A, the result of simulating the chromaticity distribution of a backlight unit according to a Comparative Example with the sequence of the LED array changed; and

FIG. 17 is a side view showing a general configuration of a display device with the surface light-emitting device according to the invention mounted on a liquid crystal display device.

### DETAILED DESCRIPTION OF THE INVENTION

Embodiments of the invention are described in more detail below with reference to the drawings attached to the present specification.

### First Embodiment

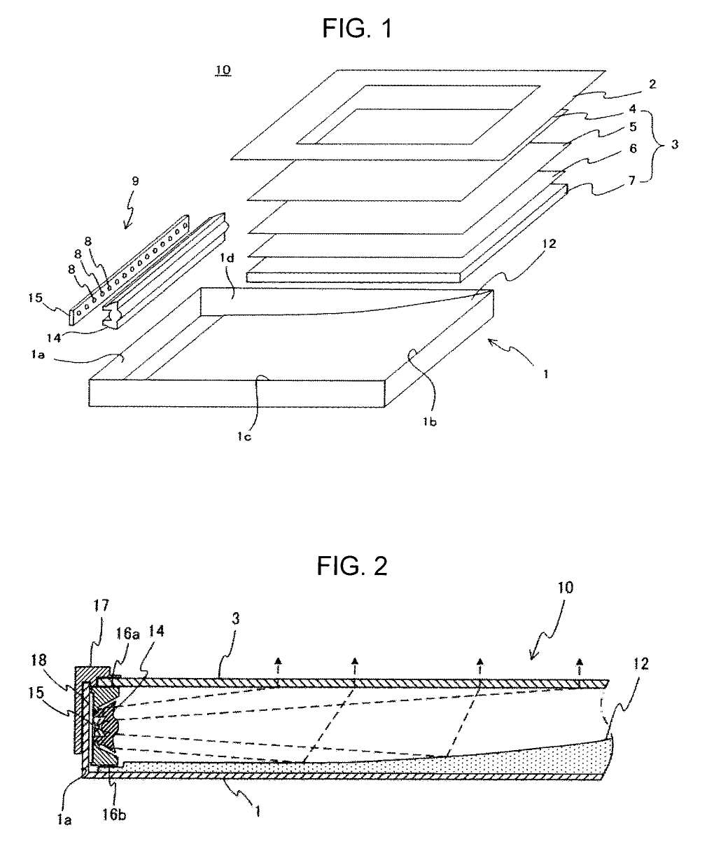

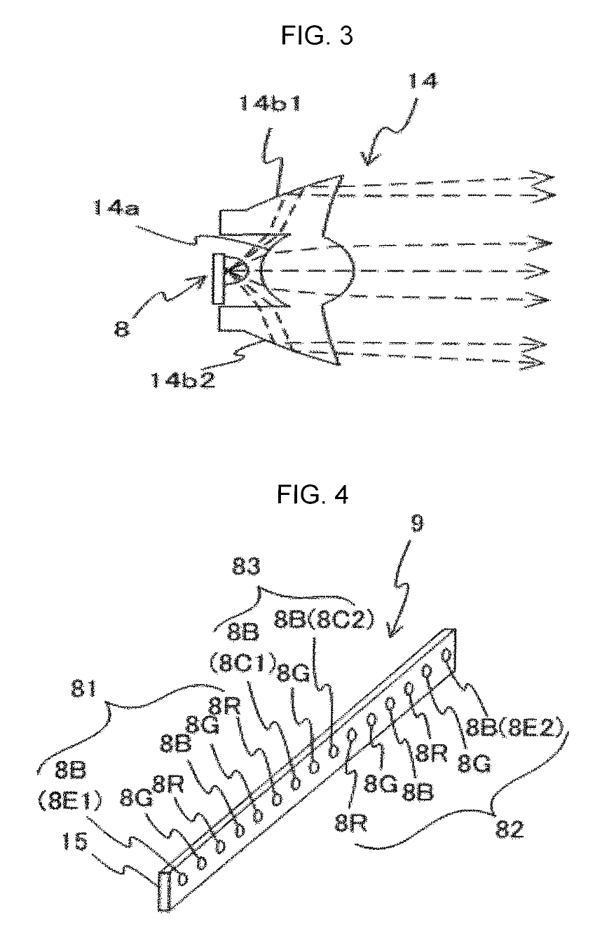

FIG. 1 is an exploded perspective view of a backlight unit 10 for a liquid crystal display device having built therein a surface light-emitting device according to a first embodiment of the invention. FIG. 2 is a partial sectional view of the backlight unit 10 shown in FIG. 1. FIG. 3 is a sectional view for explaining the path of the light emitted from the LED elements 8 and passing through a collimator lens 14. FIG. 4 is a schematic diagram for explaining an example of the configuration of an LED array 9 according to the invention.

As shown in these figures, the backlight unit 10 includes the LED array 9 as a light source with a plurality of LED elements 8 arranged substantially in alignment along a side surface 1a of a unit case 1. The LED elements 8 (8E1, 8E2) located at the end portions of the LED array 9 are arranged inside an inner peripheral edge of a front cover 2, i.e. at such positions as not to be shielded by the frame-like front cover 2 in the assembled state of the backlight unit 10. A reflector 12 formed to extend gradually toward the light-emitting surface side from the side surface 1a to a side surface 1b is arranged on a bottom surface of the unit case 1.

The opening of the unit case 1 opposed to the reflector 12 has a light-emitting surface member 3. The light-emitting surface member 3 includes a stacked unit of a diffusion sheet 4, a lens sheet 5, a diffusion sheet 6 and a diffusion plate 7. The light emitted from the LED elements 8 each passes through a hollow portion in the unit case 1, and after being scattered and mixed through the light-emitting surface member 3, emitted outside as planar light as a whole. Further, the front cover 2 in the shape of a window frame for defining the light-emitting surface covers the unit case 1 from above the light-emitting surface member 3, to define the contour of the backlight unit 10 together with the unit case 1. According to this embodiment, the space portion between the light-emitting surface member 3 and the reflector 11 in the unit case 1 makes up a hollow light guide area for transmitting the light emitted from the LED elements 8.

The unit case 1 is formed of either a metal of high heat conductivity such as aluminum or an alloy thereof or resin. In this embodiment, the unit case 1 is in the shape of a flat rectangle in a plan view. Depending on the shape of the light-emitting surface or the light-emitting device, however, a unit case having a cross section in the shape of any other polygon or other shape having at least a partial radius of curvature is also applicable according to the invention.

The backlight unit 10 according to this embodiment has the reflector 12 on the bottom surface of the unit case 1, and the reflector 12 functions as a reflection surface for guiding the light to the light-emitting surface. The reflector 12 can be formed as a multilayer unit in which the reflection surface having a high reflection property or diffusive reflection property is provided on a plate member of metal or resin. Nevertheless, the reflector 12 may alternatively be formed in one layer of a material high in reflection property or diffusive reflection property. For example, the reflector 12 may be formed by bonding or coating a substrate surface with a white PET film or white ink or by coating a member of high reflection property such as aluminum with a light diffusion agent. Alternatively, the substrate itself may be produced integrally by a known method such as injection molding with a white or opaque white resin material. Still alternatively, the bottom surface of the unit case 1 may be formed of the material described above and thus can be used as a reflection surface, instead of forming the reflector 12 as a separate member from the unit case 1. The shape of the reflection surface, which can be formed by any of various methods as described above, is not limited to that of the reflector 12 shown in the figures, but may employ any of various forms such as a rough reflection surface to provide scattered light.

Also, in order to improve utilization efficiency of light as a whole, a diffusive reflection surface or a mirror reflection surface (neither of which is shown) white or opaque white in color is preferably formed on a side surface (especially, the side surfaces 1c, 1d) of the unit case 1.

The light-emitting surface member 3 is formed as a multilayer unit including the diffusion sheet 4, the lens sheet 5, the diffusion sheet 6 and the diffusion plate 7 superposed one on another, as described above. This multilayer unit has so a high light transmittance and light diffusion property that the light emitted outside can be diffused and mixed to improve the uniformity and the brightness of the surface light emission. The light-emitting surface may alternatively be formed of a single-layer diffusion plate or a light-diffusive glass material integrated with the front cover 2, instead of the multilayer light-emitting surface member 3 of this embodiment.

An LED substrate 15 is fixed on the side surface 1a of the unit case 1, and the LED array 9 includes a plurality of LED elements arranged at predetermined intervals on the substrate 15. The LED substrate 15 is formed of any of various metals having high heat conductivity such as aluminum or an alloy thereof, or ceramics such as aluminum nitrate. The LED substrate 15 can be mounted on the side wall 1a of the unit case 1 by known means such as screwing and bonding. However, it is preferable to employ a configuration in which a double-sided tape, a sheet or a grease of high heat conductivity is interposed between the substrate 15 and the side wall 1a of the unit case 1 to facilitate the heat discharge from the LED chips.

The collimator lens 14 for condensing the light emitted from the LED elements 8 of the LED array 9 is explained with reference to FIGS. 2 and 3. FIG. 2 is a partial sectional view for explaining an example of the state in which the LED elements 8 and the substrate 15 are mounted, and schematically shows the light path. FIG. 3 is an enlarged view of the collimator lens 14 and schematically explains the path of the light emitted from the LED elements 8. The collimator lens 14 is arranged in proximity to the light-emitting side of the LED elements 8, and changes the light emitted radially from the LED elements 8 into substantially parallel light.

First, the optical characteristics of the collimator lens 14 are explained. As shown in FIG. 3, the collimator lens 14 has a convex refraction portion 14a in opposed relation to the LED elements on the extension of the main optical axis of the LED elements 8, and total reflection portions 14b1, 14b2 extending on the two sides, respectively, of the refraction portion 14a. The light that has entered the refraction portion 14a is refracted in steps into substantially parallel light while passing through an incident convex surface and an exit convex surface thereof, and then emitted into the hollow light guide area. The light incident on the total reflection portions 14b1, 14b2 from the LED elements 8, on the other hand, is totally reflected on the side surfaces of the total reflection portions 14b1, 14b2 and emitted as substantially parallel light.

The collimator lens 14 is fixedly held between the holders 16a, 16b after its position relative to the LED array 9 is set correctly. In the manner as shown, for example, a notch is formed in advance on each side surface of the collimator lens 14, and a protrusion formed on each of the holders 16a, 16b is inserted into the corresponding notch. Thus, the collimator lens 14 can be fixed on a mount member 18 together with the holders 16a, 16b. The provision of a uniform notch or a plurality of notches at predetermined intervals along the longitudinal direction (the direction perpendicular to the sheet in FIG. 2) on each side of the collimator lens 14 can prevent the deformation such as warping of the collimator lens 14 which otherwise might be caused by heat, etc. The holders 16a, 16b are fixed on the side wall 1a of the unit case 1 through the mount member 18 using known means such as screwing or bonding. In the case where the collimator lens 14 is fixed by the holders 16a, 16b as in the manner shown, an air layer is preferably interposed by forming a gap between the collimator lens 14 and the holders 16a, 16b to make the most of the total reflection takes place on the total reflection portions 14b1, 14b2.

The collimator lens 14 can be fabricated by injection molding, extrusion molding or other known means using a resin material such as polymethyl methacrylate (PMMA) or polycarbonate (PC) or a glass. According to the shown embodiment, the collimator lens 14 is assumed to have a substantially uniform cross section in the longitudinal direction for simplicity. Nevertheless, the collimator lens 14 having a different radius of curvature of the light incident portion or the light exit portion or a different interval with the LED elements may be used according to the light emission color or the model of the opposed LED elements. The collimator lens 14 illustrated herein is only one of the various forms of optical elements applicable according to the invention, and any other known optical elements such as a hemispherical lens can be used as long as the light emitted radially from the LED elements 8 can be converged and changed to the light parallel to the light-emitting member 3.

Next, a method of arranging the LED array 9 according to one feature of the invention is explained with reference to FIG. 4. In FIG. 4, the reference characters B, G, R next to the numeral “8” refer to the light emission colors of blue (B), green (G) and red (R), respectively, of the LED elements 8, 8E1, 8E2, 8C1, 8C2 located at corresponding positions, respectively.

In the LED array 9 according to an embodiment of the invention, a blue LED element 8B, a green LED element 8G and a red LED element 8R are arranged repeatedly in this order from one end. Similarly, from the other end of the LED array 9, a blue LED element 8B, a green LED element 8G and a red LED element 8R are arranged repeatedly in this order. At the center of the LED array 9, a blue LED element 8B, a green LED element 8G and a blue LED element 8B are arranged in this order. In the LED array 9 shown in FIG. 1, for example, according to this manner of arrangement, 15 LED elements are arranged in the order of BGRBGRBGBRGBRGB from one end to the other. The reference numerals 8B(8E1) and 8B(8E2) indicate the blue LED elements located at one end and the other end, respectively, of the LED array 9. Similarly, the reference numerals 8B(8C1) and 8B (8C2) indicate the blue LED elements located at the central portion of the LED array 9.

In other words, the LED array 9 according to this embodiment includes three sequence patterns 81, 82, 83. In the first sequence pattern 81, a set of LED “BGR” is repeated as BGRBGR . . . from one end of the LED arrangement. In the second sequence pattern 82, the set of LED “BGR” is repeated in reverse direction as BGRBGR . . . from the other end of the LED arrangement. The third sequence pattern 83 is located between the first sequence pattern 81 and the second sequence pattern 82 and corresponds to a joint portion for coupling the sequence patterns 81, 82. According to this embodiment, the third sequence pattern 83 includes “BGB” arranged in this order.

This arrangement of the LED array 9 equalizes the light emission at both ends of the LED array 9. Specifically, when an array is configured with the set of LED “BGR” repeated as BGR . . . BGR as in a popular conventional example, the two LED elements nearest to the walls are BG at one end and GR at the other end. Thus the chromaticity is different between two ends, thereby leading to chromaticity irregularities on the light-emitting surface. Even in the case where the array is configured so that the blue LED comes at each end, the LEDs are arranged as BGR . . . BGRB, resulting in BC at one end and RB at the other end, thereby causing a chromaticity difference between the end portions. In addition, the green LED element is generally lower in brightness than the blue and red LED elements, and therefore, liable to develop brightness irregularities. Further, the red light emission color is visually recognizable by the human being more easily than the other colors, and therefore, the light emitted from the assembly mounted on the display device will cause a remarkable difference in color shade (colorfulness) difference to a degree more than the chromaticity difference obtained by measurement. In the configuration of the LED array according to an example of the present embodiment, by contrast, a plurality of LED elements having different light emission colors are arranged symmetrically at the end portions of the LED array, and therefore, the difference in chromaticity and color shade can be prevented.

According to one feature of the invention, the light emitted from the LED elements 8E1, 8E2 located at the end portions of the LED array 9 has a lower light flux than the light emitted from the other blue LED elements 8B. Since each of the LED elements 8E1, 8E2 has an adjacent LED element 8 only on one side, the blue color of the light, which is emitted from the LED elements 8E1, 8E2, is dominant in the light in the vicinity of the inner peripheral surface of the front cover 2. By reducing the light flux of the LED elements 8E1, 8E2 located at the ends of the LED array 9, light having equal chromaticity to that in the area distant from the end portions can be generated. As specific means for reducing the light flux of the light emitted from the LED elements 8E1, 8E2, means of controlling the drive current supplied to them downward, means of selecting an LED element low in light flux rank, or means of providing means for partially shielding only the light emitted from the LED elements 8E1, 8E2 may be employed.

By reducing the light flux of the LED elements 8E1, 8E2 at the end portions of the LED array 9 as described above, a more uniform chromaticity can be secured also at the edges of the light-emitting surface. A reduced light flux, however, is liable to reduce the brightness and may develop brightness irregularities. It is therefore preferable that the light flux is reduced to the range of about 40 to 80% of the average value for the LED elements of the same color in the remaining areas.

Referring again to FIG. 4, the third sequence pattern 83 is explained. According to this embodiment, the third sequence pattern 83 includes the blue LED element 8B(8C1), the green LED element 8G and the blue LED element 8B(8C2). The third sequence pattern 83 is located between the first sequence pattern 81 and the second sequence pattern 82 arranged in the manner described. The blue LED elements 8C1, 8C2 located next to and on both sides of the green LED element 8G emit a lower light flux than the remaining blue LED elements.

The third sequence pattern 83 can be explained more specifically bellow. In the case where the LED elements are arranged as BGRBGR . . . repeatedly from both sides of the LED array 9 symmetrically as in the example of FIG. 4, the joint portion becomes “BGRRGB” in which two LEDs emitting light emission of the same color “R” are arranged adjacently to each other. In that case, the red color light necessarily has a dominant effect and the chromaticity on the light-emitting surface lacks uniformity. In the case where the LED elements emitting the same color are arranged adjacently to each other, therefore, one of them is preferably removed. As a result, the chromaticity irregularities on the light-emitting surface can be obviated.

As described above, one of the LED elements R adjacently arranged in the sequence “BGRRGB” in the joint portion between the first sequence pattern 81 and the second sequence pattern 82 is removed to obtain the sequence “BGRGB”. According to this embodiment, however, this sequence is further replaced by the sequence “BGB”. In other words, the sequence “GRG” including one LED element R and two LED elements G on both sides thereof, which is left after removing one of the adjacent LED elements of the same type, is replaced by one “G”. This is because the wavelength peak of the green (G) light is approximate to the wavelength range easily recognized by human eyes, and the arrangement of two elements G on both sides of one element R will increase the brightness in the area corresponding to this joint portion, thereby causing brightness irregularities. According to the present embodiment, this problem is alleviated or solved by replacing the “GRG” with “G” in the joint portion. At the same time, the two elements B (8C1 and 8C2 in FIG. 4) arranged adjacently to the element G on both sides thereof are set to emit a lower light flux than the remaining blue LED elements.

The very existence of the third pattern 83 disturbs the periodicity of the sequence of the LED array 9 as a whole. By reducing the light flux of each light emitted from the LED elements 8C1, 8C2, however, the occurrence of the chromaticity irregularities can be prevented.

As shown in the example of FIG. 1, when the third sequence pattern 83 is arranged at the center of the LED array 9, the LED elements 8 (8B, 8G, 8R) having different light emission colors are arranged symmetrically, thereby obtaining the light emission having a uniform chromaticity and brightness. The light flux of the LED elements 8C1, 8C2 is preferably reduced to the range of about 60 to 90% of the averaged value for the LED elements of the same color in the remaining areas.

In the embodiment described, although the LED elements 8R, 8G, 8B for emitting the light of the three different colors of red, green and blue are used for the LED array 9, substantially equal advantage can also be obtained by use of the LED elements having any number of different light emission colors.

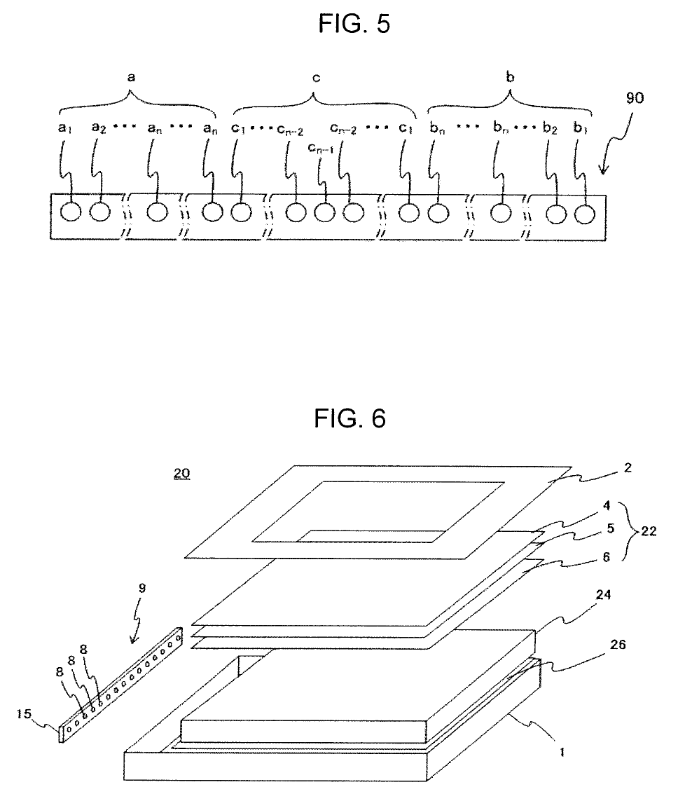

Next, an example of the configuration of the LED array 9 having n types of the LED elements of different light emission colors is explained with reference to FIG. 5. In the description that follows, a first LED element is defined as an LED element having a first light emission color, and an nth LED element as an LED element having an nth light emission color. Here, “n” is any natural number not smaller than 3. Like in the aforementioned embodiment, the LED array includes a first sequence pattern a, a second sequence pattern b and a third sequence pattern c. The first sequence pattern a is one in which “a₁, a₂, . . . , aₙ” is repeated at least twice from one end portion of the LED array, where the reference character “a” of “aᵢ” indicates the LED element making up the first sequence pattern a, and the subscript “i” indicates the ith LED element (i=1, 2, . . . , n).

The second sequence pattern b is one in which “b₁, b₂, . . . , bₙ” is repeated at least twice from the other end portion, where the reference character “b” of “bⱼ” indicates an LED element making up the second sequence pattern b, and the subscript “j” indicates the jth LED element (j=1, 2, . . . , n). The 1st, 2nd, . . . , nth LED elements b₁, b₂, . . . , bₙ are substantially identical with the LED elements a₁, a₂, . . . , aₙ, respectively, making up the first sequence pattern a, except that these LED elements are arranged in reverse order so that the light emission conditions in the neighborhood of the end portions of the LED array 90 are symmetric to each other.

In another form of the invention, however, the LED elements different in light flux rank or chromaticity rank may be used for the first sequence pattern a and the second sequence pattern b. In this case, by arranging a second LED array at a position in opposed relation to a first LED array, and mixing the light emitted from the two LED arrays, a uniform surface light emission can be produced as a whole.

The third sequence pattern c is interposed between the first sequence pattern a and the second sequence pattern b and includes the LED elements c₁, c₂, . . . , cₙ₋₁, cₙ, cₙ₋₁, . . . , c₂, c₁. In the reference character “cₖ”, the character “c” indicates an LED element making up the third sequence pattern c, and the subscript “k” indicates a kth LED element (k=1, 2, . . . , n). The third sequence pattern c, though preferably arranged at the center of the LED array 90, is not necessarily limited to be arranged at a specified position as long as it is sufficiently distant from the end portions of the LED array 90. In particular, in the case where a pair of LED arrays are arranged on both side surfaces of the device housing (e.g. the unit case 1 in FIG. 1), the third sequence pattern c of one of the LED arrays may be displaced toward one side from the central position, while the sequence pattern of the other LED array may be displaced to the other side. In this way, the light distribution is staggered, and the resulting mutual complementation can produce a uniform surface light emission as a whole.

As in the first embodiment using the LED elements 8 of three colors (RGB), the LED element a₁ and the LED element b₁ located at the end portions of the LED array 90 are set to emit a lower light flux than the averaged light flux of the first LED elements a₁, b₁, c₁ arranged in the remaining areas. Also, in the case where the LED elements of the same type (for example, the nth LED element cₙ) are adjacent to each other in the third sequence pattern c, one of the adjacent LED elements of the same type is removed, while the two LED elements adjacent to both sides of the remaining LED element (for example, the (n−1)th LED elements cₙ₋₁) are set to emit a lower light flux than the average light flux of the LED elements of the same type in the remaining area (for example, aₙ₋₁ bₙ₋₁).

By configuring the LED array in this way and reducing the light flux of predetermined LED elements, the light emission at the end portions of the LED array and the light emission chromaticity at the central portion of the LED array which otherwise might be caused by the irregular element arrangement of the LED array can be made uniform, thereby making it possible to provide a high-quality surface light emission, which is uniform over the light-emitting surface as a whole.

In the example shown in FIG. 5, the central portion of the third sequence pattern c is configured as cₙ₋₁, cₙ, cₙ₋₁ arranged in this order. This pattern, however, may be replaced with, for example, cₙ₋₂, c_{n-1,} cₙ₋₂. This corresponds to the embodiment of FIG. 4 explained with reference to an example using the LED elements of RGB (cₙ₋₁ corresponds to G, and cₙ₋₂ to B). In other embodiments, the sequence at the central portion may be selected as cₙ₋₃, cₙ₋₂, c_{n-3,} for example, and is not limited to the shown specific example.

More specifically, in the light source arrangement with a plurality of spot light sources arranged in sequence, the light flux of the light emitted from the light sources arranged at the end portions of the sequence is set to emit a lower light flux than the averaged light flux of the light emitted from the remaining light sources. In this way, the effect due to the unique light distribution for the end portions of the sequence pattern can be minimized while at the same time obviating the chromaticity irregularities.

In addition, according to one aspect of the invention, a third sequence pattern formed in a predetermined sequence is incorporated between first and second sequence patterns each formed of a predetermined repetitive sequence from the end portions of the LED array on the one hand, and the LED elements located at the end portions of the LED array are reduced in light flux as compared with the other LED elements on the other hand. In this way, the chromaticity irregularities can be reduced both at the end portions and the central portion of the array. The conventional LED array including an arrangement of a plurality of monochromatic LEDs is configured as repetitive predetermined sequences of, for example, BGRBGRBGR . . . . If such simple repetitive sequences are employed, the light emission distributions at both ends of the LED array may be considerably different from each other (in the case where the blue LED is arranged at each end, for example, the two LED elements are blue and green at one end of the array, while the two LED elements at the other end are red and blue).

In the LED arrangement according to the invention, the aforementioned problem is not posed since the LED elements are arranged in a predetermined repetitive pattern from each end so that the light distributions at both ends of the array are symmetric to each other. In addition, the chromaticity irregularities at the end portions are eliminated by reducing the light flux of the LED elements located at the end portions as described above. Further, by incorporating the third sequence pattern of a predetermined sequence, the chromaticity irregularities thus far caused due to the unique color mixing conditions at the boundary between the first and second sequence patterns can be alleviated, while at the same time reducing the chromaticity irregularities which otherwise might occur at the central portion of the array.

Furthermore, by reducing the light flux of predetermined LED elements in the third sequence pattern, the chromaticity irregularities which otherwise might be caused by the disturbance of the periodicity of the LED array can be further reduced.

### Second Embodiment

Next, with reference to FIG. 6, the backlight unit 20 according to a second embodiment of the present invention is explained. In FIG. 6, the components corresponding to those of the backlight unit 1 shown in FIG. 1 are designated by the same reference numerals, respectively, and the structure, the operation or the fabrication method of such components will not be explained in detail to avoid repetitive explanation. Mainly, therefore, only different parts will be explained below.

The backlight unit 20 has a light guide member 24 in the space defined by a unit case 1 and a light-emitting surface member 22 (a diffusion sheet 4, a lens sheet 5 and a diffusion sheet 6). Further, in the backlight unit 20, a reflection sheet 26 for improving light utilization efficiency is arranged between a bottom surface of the unit case 1 and the light guide member 24. The light emitted from each of the plurality of the LED elements 8 making up the LED array 9 is transmitted while being diffused and mixed in the light guide member 24 formed of transparent resin, and discharged outside as a planar light along the shape of the light guide member 24. The shape of the planar light-emitting surface is not limited to a rectangle, but a polygon or any shape partially having a radius of curvature may be employed.

The light guide member 24 can be fabricated by a known method such as injection molding or extrusion molding using a transparent resin material such as PMMA (polymethyl methacrylate) or PC (polycarbonate) The light guide member 24 is formed in any of various shapes according to the desired shape of the light-emitting surface.

The optical elements such as the collimator lens 14 arranged in proximity to the light-emitting side of the LED elements 8 according to the first embodiment are not required in this embodiment. This is because the light can be guided by use of the light guide member 24, which is high in light diffusion and transmittance, in this embodiment, as compared with the first embodiment in which the hollow area functions substantially as a light guide area and in which the light from the LED is not enough to go straight and is comparatively low in directivity, thereby making it difficult to use the LED as it is. Even when the light guide member 24 is used, however, an optical element such as the collimator lens 14 having a condense property may also be used in combination as necessary.

The LED array 9 according to the second embodiment, like in the first embodiment, is arranged with the predetermined sequence of the LED elements according to one of the features of the invention.

### Third Embodiment

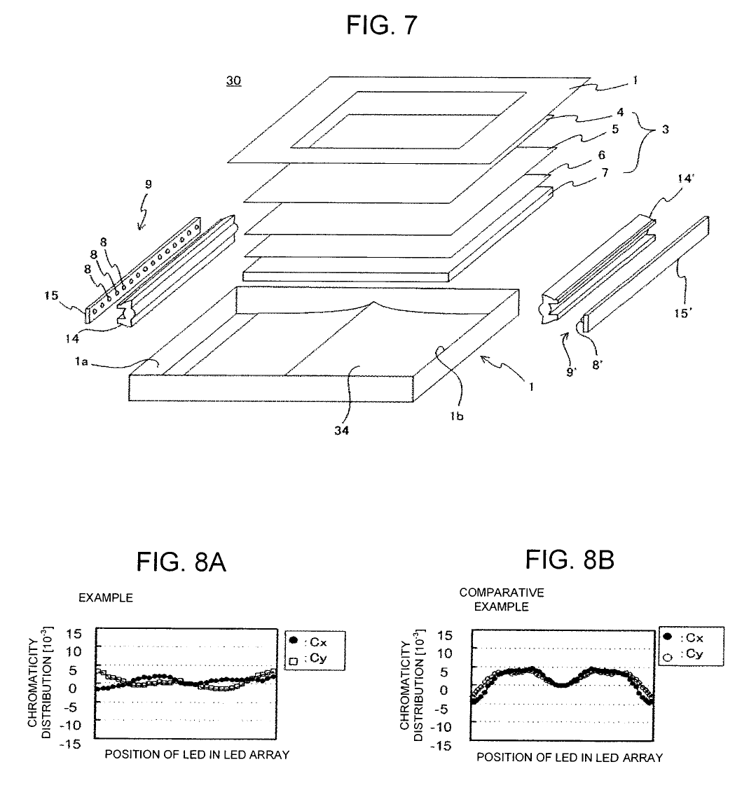

FIG. 7 is an exploded perspective view of a backlight unit 30 according to a third embodiment of the present invention. Also in FIG. 7, the components corresponding to those of the backlight unit 1 shown in FIG. 1 are designated by the same reference numerals, respectively, and the structure, the operation or the fabrication method of such components will not be explained in detail to avoid repetitive explanation. Mainly, therefore, only different parts will be explained below. The backlight unit 30 includes a pair of LED arrays 9, 9′ and collimator lenses 14, 14′ arranged in opposed relation to each other along the side surfaces 1a, 1b, respectively, of the unit case 1. A reflector 34 arranged on the bottom surface of the unit case 1, which has a similar function to the reflector 12 of the first embodiment, has a central part raised in the shape of a substantially symmetric hill to reflect or diffusively reflect the light emitted in opposite directions from the LED elements 8, 8′.

The LED array 9′ has an LED sequence equivalent to the LED array 9 according to the first embodiment of the invention. Specifically, the LED elements 8 are arranged in a predetermined repetitive pattern as first and second sequence patterns from one and the other ends, respectively, of the LED array 9, and the LED elements 8 are arranged according to a third sequence pattern at the central portion thereof. The LED elements 8 arranged at predetermined positions are controlled to emit a lower light flux than the other LED elements. In particular, according to the embodiment, the third sequence pattern does not have to be located at the central portion as long as it is sufficiently distant from the end portions of the LED array 9. For example, the third sequence pattern of the one LED array 9 may be displaced from the center toward one side, while the third sequence pattern of the other LED array 9′ may be displaced toward the opposite side. In this way, the light distribution is staggered and complements each other, thereby providing a uniform surface light emission as a whole.

Although the LED elements 8 are substantially aligned in a single row on the substrate 15 according to the aspects described above, the invention is also applicable to the arrangement of the LED elements 8 in a plurality of rows on the substrate 15 with equal function. In the case where the LED elements 8 are arrayed in a plurality of rows, the LED rows may be zigzagged in longitudinal direction. In this case, predetermined LED elements in at least one of the plurality of rows of the LED array may be reduced in light flux, and the sequence pattern according to the embodiment does not have to be applied to all the LED arrays.

### Comparison between Examples of the invention and Comparative Examples

Next, with regard to the backlight unit having the LED array configured according to the embodiments of the present invention, the result of actual measurement of the light emission color distribution is explained as a comparison with the backlight unit according to a comparative example having the LED array to which the invention is not applied.

### (Experiment 1)

FIGS. 8A and 8B are diagrams showing the experimental result of measuring the distribution of Cx and Cy in a chromaticity coordinate system for an Example of the embodiment of the present invention in which the LED elements at predetermined positions are set to emit a low light flux according to the embodiment of the present invention and a Comparative Example in which all the LED elements have a substantially equal light flux in a backlight unit having an LED array including 57 LED elements (18 red LED elements, 19 green LED elements and 20 blue LED elements). FIG. 8A is a graph showing the measurement result according to the Example of the embodiment of the present invention, and FIG. 8B is a graph showing the measurement result according to the Comparative Example.

In the LED arrays according to the Example and the Comparative Example, the LED elements are arranged in the order of BGRBGR . . . BGRBGBRGB . . . RGBRGB (where “B” indicates a blue LED, “C” a green LED and “R” a red LED, as applicable similarly in the description that follows). The LED elements BGRBGR . . . BGR making up a part of the LED array are those arranged based on a first sequence pattern. Similarly, the LED elements RGB . . . RGBRGB making up a part of the LED array are those based on a second sequence pattern. A third sequence pattern including three LED elements of BGB is arranged between the first and second sequence patterns.

In the Example, the blue LED elements arranged at the ends of the LED array are both set to emit a lower light flux, and so are the two blue LED elements in the third sequence pattern. For the blue LED elements to be reduced in light flux, LEDs of the light flux rank as low as 200 mW in the radiation flux at the drive current of 350 mA were used, while, for the remaining blue LED elements, those having the average radiation flux of 250 mW were used. The red LED elements were those in the rank of the average light flux of 451 m at the drive current of 350 mA, and the green LED elements were in the rank of the average light flux of 851 m at the drive current of 350 mA. The experiment was conducted under the drive conditions of 240 mA for the blue LED elements, 210 mA for the green LED elements and 160 mA for the red LED elements.

In the backlight unit having the light-emitting surface of 330 mm by 435 mm, the measurement point was set at a position 40 mm distant from the side edge (inner edge of the front cover of the unit) of the light-emitting surface nearer to the light source. In the graph, the abscissa represents the distance from the end portions of the LED array in the direction parallel to the LED array and the ordinate represents the deviation of the chromaticity Cx or Cy from the center point as a reference (0). Specifically, the relation holds that (numerical value of ordinate)=(chromaticity Cx or Cy at measurement point)−(chromaticity Cx or Cy at center). The reference characters Cx and Cy represent the numerical values corresponding to the respective components of the chromaticity coordinate. The chromaticity Cx and Cy at the center of the array according to the Example were 0.252 and 0.225, respectively.

According to the Example, as apparent from the comparison of the result between the Example shown in FIG. 8A and the Comparative Example shown in FIG. 8B, a satisfactory result that both the light emission chromaticities Cx and Cy were more uniform along the direction of arrangement of the LED array was obtained.

Next, with regard to the light emission chromaticity distribution of the backlight unit according to an Example of the embodiment of the present invention, the result obtained by simulations using the computer instead of the actual measurement described above is explained together with a Comparative Example. Light Tools of Optical Research Associates (ORA) was used for the simulation described below.

### (Simulation 1)

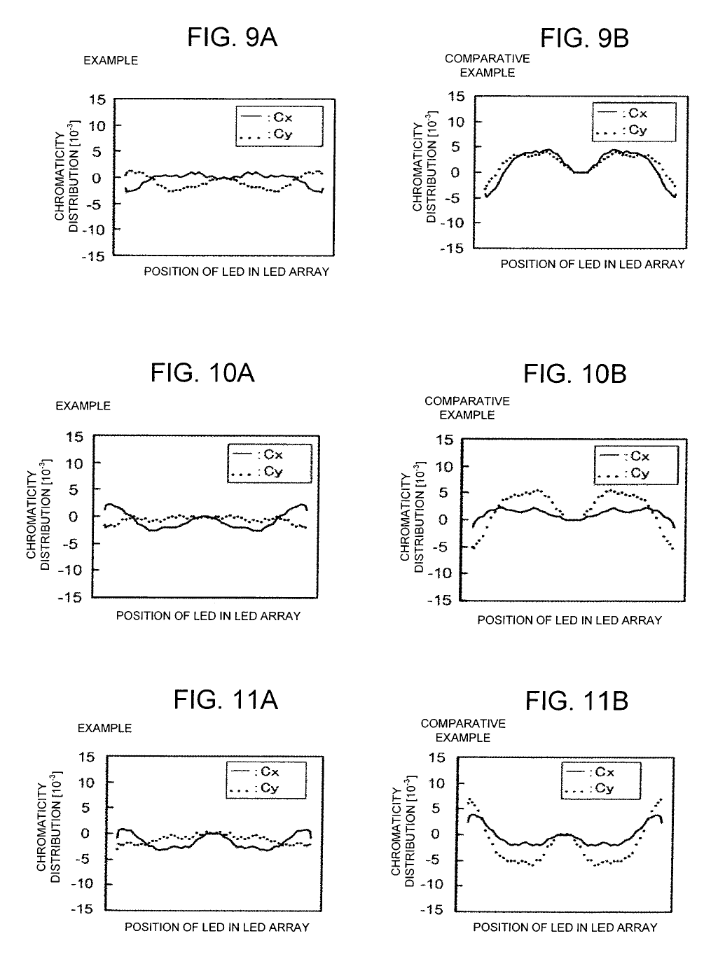

FIGS. 9A and 9B are graphs showing the results of the simulation in which the light emission chromaticity distribution was calculated for backlight units each employing LEDs of three colors RGB. In each of backlight units according to an Example and a Comparative Example, like in the first experiment described above, an LED array with 57 LED elements arranged in the order of BGR . . . BGRBGBRGB . . . RGBRGB was used. In the backlight according to the Example, however, an LED array with predetermined LED elements reduced in light flux according to the invention was used. In the Comparative Example, on the other hand, an LED array not adjusted in light flux as described above was used. Also, the measurement point, like in the first experiment, was selected at a position 40 mm from the side edge of the light-emitting surface. The blue LED elements located at the end portions of the array each had the light flux 50% of the average light flux of the other blue LED elements, and the blue LED elements making up the centrally located third sequence pattern each had 70% of the average light flux of the other blue LED elements.

Comparison between the simulation result according to the Example shown in FIG. 9A and the simulation result for the Comparative Example shown in FIG. 9B apparently confirms that the chromaticity distribution in the backlight unit according to the Example of the invention was also remarkably uniform in the calculation result of the simulation as in the actual measurement.

### (Simulation 2)

FIGS. 10A and 10B are graphs showing the results of calculating the light emission color distribution with the LED elements replaced by other type of LED in the backlight units using the LED elements of the three different colors of RGB as light sources. In the backlight unit according to an Example, the LED array had the LED elements arranged in the order of BRGBRG . . . BRGBRBGRB . . . GRBGRB. The blue LED elements located at the end portions had the light flux 50% of the average light flux of the other blue LED elements, and the blue LED elements at the central portion had 70% of the average light flux of the other blue LED elements. FIG. 10A shows the result of calculating the chromaticity distribution in the backlight unit according to the Example.

In the backlight unit according to a Comparative Example, on the other hand, though having the LED elements arranged in the same way as the backlight unit according to the embodiment, the LED array was used without light flux adjustment as described above. FIG. 10B shows the result of calculating the chromaticity distribution in the backlight unit according to the Comparative Example.

The measurement point and other calculation conditions were similar to those of the first simulation.

As apparent from the result of simulation according to the Example shown in FIG. 10A and the result of simulation according to the Comparative Example shown in FIG. 10B, the calculation result of the simulation also confirms that the chromaticity distribution in the backlight unit Example of according to the embodiment of the present invention was remarkably uniform.

Unless otherwise specified, the measurement point and other calculation conditions in the Simulations 3 to 8 described below were also the same as those of the Simulation 1.

### (Simulation 3)

FIGS. 11A and 11B are diagrams showing the simulation results using the LED array having the LED elements of the three colors RGB arranged in the order of GRBGRB . . . GRBGRGBRG . . . BRGBRG. In the backlight unit according to an Example, the light flux of the green LED elements located at the end portions was set at 50% of the average light flux of the other green LED elements, the light flux of the centrally located green LED elements was set at 65% of the average light flux of the other green LED elements, and the light flux of the second red LED element from each end of the array was set at 80% of the average light flux of the other red LED elements. The light emission chromaticity distribution of the backlight unit in this case is shown in FIG. 11A.

The backlight unit according to a Comparative Example, on the other hand, used an LED array which was formed of the LED elements arranged in the same order as in the Example, but was not adjusted in light flux. The calculation result for this case is shown in FIG. 11B.

As apparent from the result of simulation according to the Example shown in FIG. 11A and the result of simulation according to the Comparative Example shown in FIG. 11B, the calculation result for simulation also confirms that the chromaticity distribution in the backlight unit according to the Example of the invention was remarkably uniform.

### (Simulation 4)

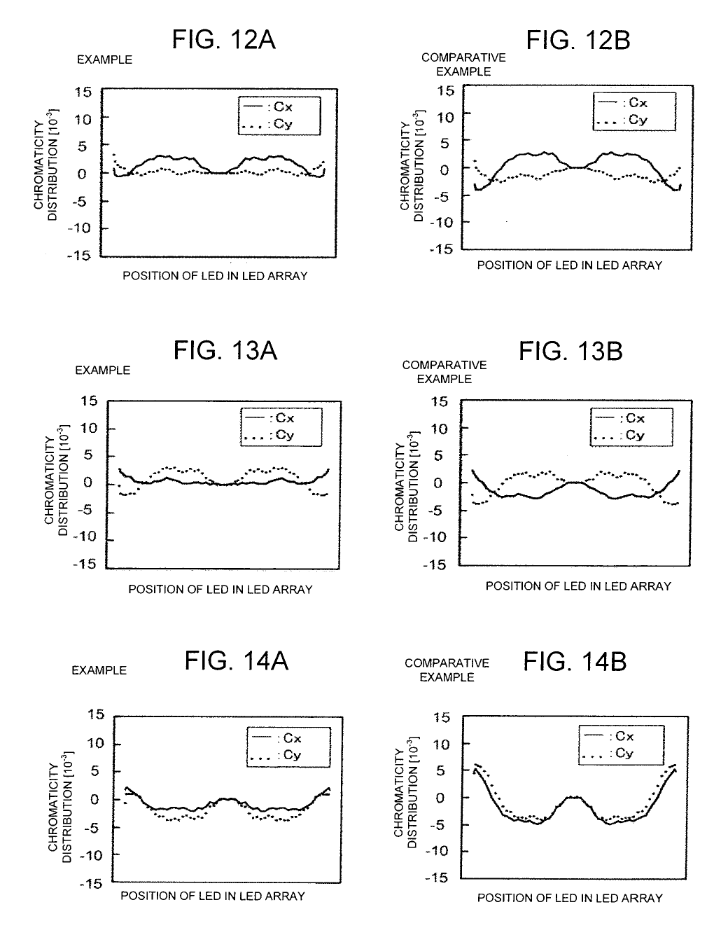

FIGS. 12A and 12B are graphs showing the results of simulating the light emission chromaticity distribution of the backlight units using the LED array having the LED elements of three colors of RGB arranged in the order of GBRGBR . . . GBRGBGRBG . . . RBGRBG. In the backlight unit according to an Example, the light flux of the green LED elements located at the end portions was set at 70% of the average light flux of the other green LED elements. Similarly, the light flux of the centrally located green LED elements was set at 90% of the average light flux of the other green LED elements and the light flux of the second blue LED element from each end of the array was set at 80% of the average light flux of the other blue LED elements. The light emission chromaticity distribution of the backlight unit in this case is shown in FIG. 12A.

In the backlight unit according to a Comparative Example, on the other hand, though having an array formed of the LED elements arranged in the same order as in the Example, the light flux was not adjusted. The light emission chromaticity distribution of the backlight unit for this case is shown in FIG. 12B.

As apparent from the result of simulation according to the Example shown in FIG. 12A and the result of simulation according to the Comparative Example shown in FIG. 12B, the calculation result for simulation also confirms that the chromaticity distribution in the backlight unit according to the Example of the invention was remarkably uniform.

### (Simulation 5)

FIGS. 13A and 13B are graphs showing the results of simulation using the LED array having the LED elements of three colors RGB arranged in the order of RBGRBG . . . RBGRBRGBR . . . GBRGBR. In the backlight unit according to an Example, the light flux of the red LED elements located at the end portions was set at 70% of the average light flux of the other red LED elements. Similarly, the light flux of the centrally located red LED elements was set at 80% of the average light flux of the other red LED elements, and the light flux of the second blue LED element from each end of the array was set at 90% of the average light flux of the other blue LED elements. The light emission chromaticity distribution of the backlight unit in this case is shown in FIG. 13A.

In the backlight unit according to a Comparative Example, on the other hand, the light flux was not adjusted for the LED array with the LED elements arranged the same way as in the embodiment. The light emission color distribution of the backlight unit in this case is shown in FIG. 13B.

As apparent from the result of simulation according to the Example shown in FIG. 13A and the result of simulation according to the Comparative Example shown in FIG. 13B, the calculation result for simulation also confirms that the chromaticity distribution in the backlight unit according to the Example of the invention was remarkably uniform.

### (Simulation 6)

FIGS. 14A and 14B are graphs showing the simulation results using the LED array having the LED elements of three colors RGB arranged in the order of RGBRGB . . . RGBRGRBGR . . . BGRBGR.

In the backlight unit according to an Example, the light flux of the red LED elements located at the end portions was set at 80% of that of the average light flux of the other red LED elements. Similarly, the light flux of the centrally located red LED elements was set at 80% of the average light flux of the other red LED elements, and the light flux of the second green LED element from each end of the array was set at 80% of the average light flux of the other green LED elements. The light emission chromaticity distribution of the backlight unit in this case is shown in FIG. 14A.

In the backlight unit according to a Comparative Example, on the other hand, the light flux was not adjusted for the LED array having the same element arrangement as in the Example. The light emission color distribution of the backlight unit in this case is shown in FIG. 14B.

As apparent from the simulation results according to the Example shown in FIG. 14A and the simulation result for the Comparative Example shown in FIG. 14B, the result of calculation for the simulation also confirms that the chromaticity distribution in the backlight unit according to the Example of the invention was remarkably uniform.

### (Simulation 7)

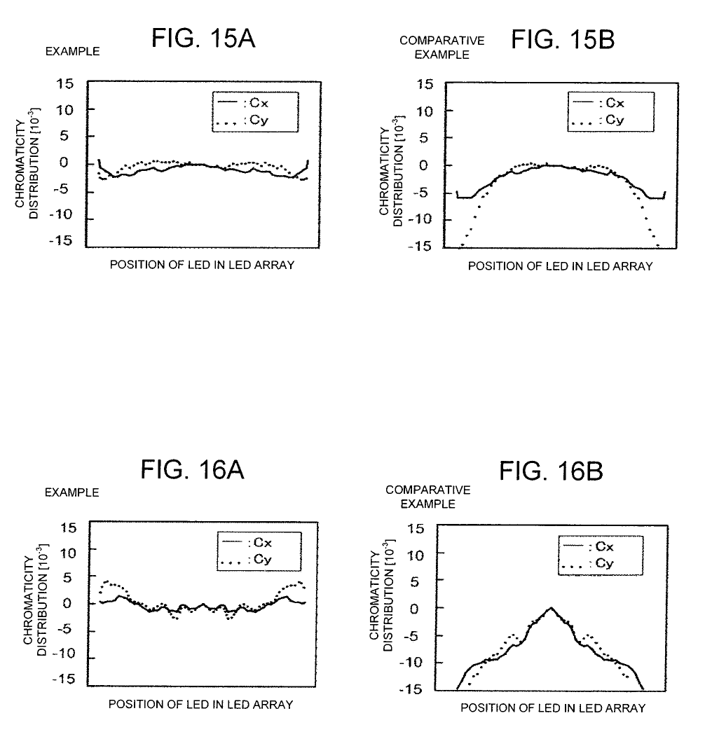

FIGS. 15A and 15B are graphs showing the results of calculating the light emission chromaticity distribution in the backlight units using the LED elements of four colors of red, green, blue and cyan as light sources. In the LED array according to an Example, the light elements are arranged in the order of BGRCBGRC . . . BGRCBGRGBCRGB . . . CRGBCRGB (where “C” indicates the LED element having the light emission color of cyan, which is applicable in the description that follows). The light flux of the blue LED elements located at the end portions of the array was set at 60% of the average light flux of the other blue LED elements. The light emission chromaticity distribution of the backlight unit in this case is shown in FIG. 15A.

In the backlight unit according to a Comparative Example, on the other hand, the LED array having the same element sequence as in the Example is used, but the light flux was not adjusted. The light emission chromaticity distribution of the backlight unit in this case is shown in FIG. 15B.

As apparent from the simulation result according to the Example shown in FIG. 15A and the simulation result for the Comparative Example shown in FIG. 15B, the result of calculation for the simulation also confirms that the chromaticity distribution in the backlight unit according to the Example of the invention was remarkably uniform.

### (Simulation 8)

FIGS. 16A and 16B are graphs showing the results of calculating the light emission chromaticity distribution in the backlight units using the LED elements of five colors of red, green, blue, cyan and yellow as light sources. In the LED array according to an Example, the light elements were arranged in the order of BGRCYBGRCY . . . BGRCYBGRCRGBYCRGB . . . YCRGBYCRGB (wherein “Y” indicates the LED element having the light emission color of yellow). The light flux of the blue LED elements located at the end portions of the array was set at 50% of the average light flux of the other blue LED elements. Similarly, the light flux of the red LED elements adjacent to the centrally located cyan LED element was set at 70% of the average light flux of the other red LED elements, and the light flux of the green LED elements adjacent to the centrally located red LED element reduced in light flux was set at 80% of the average light flux of the other green LED elements. The light emission chromaticity distribution of the backlight unit in this case is shown in FIG. 16A.

In the backlight unit according to a Comparative Example, on the other hand, the LED array having the same sequence of the LED elements was used, but the light flux was not adjusted. The light emission chromaticity distribution of the backlight unit in this case is shown in FIG. 16B.

As apparent from the simulation result according to the Example shown in FIG. 16A and the simulation result for the Comparative Example shown in FIG. 16B, the calculation result for simulation also confirms that the chromaticity distribution in the backlight unit according to the Example of the invention was remarkably uniform.

As described above, according to an aspect of the present invention, a uniform light emission chromaticity distribution can be obtained by reducing the light flux of the predetermined LED elements even in the case where the number of the light emission colors of the light sources used is increased or the sequence of the light sources is changed.

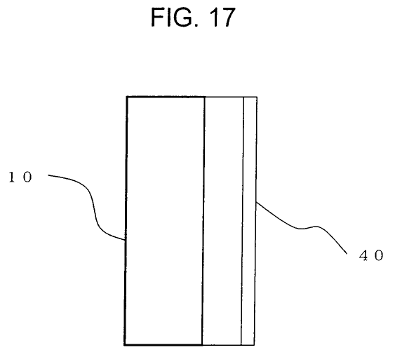

According to another aspect of the present invention, there is provided a surface light-emitting device which can produce the satisfactory surface light emission having only small chromaticity irregularities by a simple method. The surface light-emitting device according to still other aspect of the present invention, therefore, can be used as a liquid crystal backlight source having a general configuration as shown in FIG. 17. Specifically, in FIG. 17, the surface light-emitting device 10 described above is arranged on the rear surface of a liquid crystal display panel 40. Also, the surface light-emitting device according to the invention is applicable to various technical fields, though not shown, including a signboard light sources and an ordinary illumination device emitting the surface light.

What is claimed is:

1. A surface light-emitting device comprising:
a hollow housing having a reflection surface arranged on a bottom surface thereof and a light-emitting surface arranged at a position in opposed relation to the reflection surface; and
a plurality of spot light sources aligned along at least one side surface of the housing to emit light of different colors;
wherein light emitted from spot light sources located at end portions of a spot light source sequence including the plurality of spot light sources emits a lower light flux than an averaged light flux of light emitted from the other spot light sources.

2. A surface light-emitting device comprising:
a hollow housing having a reflection surface arranged on a bottom surface thereof and a light-emitting surface arranged at a position in opposed relation to the reflection surface; and
an LED array including a plurality of LED elements aligned along at least one side surface of the housing;
wherein the LED array includes n (n: natural number of 3 or more) types of LED elements having different light emission colors;
wherein sequences of the LED elements in the LED array includes:
a first sequence pattern in which n LED elements including a first LED element having a first light emission color to an nth LED element having an nth light emission color are arranged repetitively in an order of 1, 2, 3, . . . , n from one end of the LED array;
a second sequence pattern in which n LED elements including a first LED element having a first light emission color to an nth light emission color are arranged repetitively in the order of 1, 2, 3, . . . , n from another end of the LED array; and
a third sequence pattern formed at the inter mediate position between the first sequence pattern and the second sequence pattern;
wherein one of the LED elements of the same type adjacent to each other in the third sequence pattern is removed, and the light emitted from two LED elements adjacent to both sides of the remaining LED element and the light emitted from the first LED element located at each end of the LED array emit a lower light flux than an averaged light flux of the light emitted from the LED elements of the same type, respectively, located at the other positions.

3. The surface light-emitting device according to claim 2,
wherein the LED array includes at least an LED element for emitting green (G), and in the case where the two LED elements adjacent to the both sides of the LED element remaining as a result of removing one of the adjacent LED elements of the same type are green (G) LED elements in the third sequence pattern, the remaining LED element and the two green (G) LED elements adjacent to the sides of the remaining LED element are replaced by one green (G) LED element.

4. The surface light-emitting device according to claim 2,
wherein the LED array includes LED elements of at least three types for emitting the light of red (R), green (G) and blue (B), and in the case where the LED element sequence becomes one of GRG and GBG as a result of removing one of the adjacent LED elements of the same type in the third sequence pattern, the LED element sequence is replaced by one LED element of green (G).

5. The surface light-emitting device according to claim 3, further comprising a collimator lens arranged in the vicinity of the LED array to condense emitted light from the LED elements into substantially parallel light.

6. The surface light-emitting device according to claim 4, further comprising a light guide member arranged in an internal space of the housing between the reflection surface and the light-emitting surface thereof to guide the light from the LED elements to the light-emitting surface.

7. The surface light-emitting device according to claim 5,
wherein the joint portion for coupling the first sequence pattern and the second sequence pattern is located substantially at a center of the LED array.

8. The surface light-emitting device according to claim 2,
wherein the LED array is arranged along each of a pair of opposed side surfaces of the housing, and the reflection surface is substantially in the shape of a hill raised between the pair of the side surfaces of the housing.

9. The surface light-emitting device according to claim 2, further comprising a collimator lens arranged in the vicinity of the LED array to converge radially emitted light from the LED elements into substantially parallel light.

10. The surface light-emitting device according to claim 9,
wherein the joint portion for between the first sequence pattern and the second sequence pattern is located substantially at a center of the LED array.

11. The surface light-emitting device according to claim 10,
wherein the LED array is arranged along each of a pair of opposed side surfaces of the housing, and the reflection surface is substantially in the shape of a hill raised between the pair of the side surfaces of the housing.

12. The surface light-emitting device according to claim 2, further comprising a light guide member arranged in an internal space of the housing between the reflection surface and the light-emitting surface thereof to guide the light from the LED elements to the light-emitting surface.

13. A display device comprising the surface light-emitting device according to claim 1 as a light source.
